(19) United States
(12) Patent Application Publication
(10) Pub. No.: US 2013/0118569 A1
(43) Pub. Date: May 16, 2013

(54) METHOD FOR FORMING THIN FILM SOLAR CELL WITH BUFFER-FREE FABRICATION PROCESS

(71) Applicants: Wen-Chin Lee, Baoshan Township (TW); Liang-Sheng Yu, Kaohsiung City (TW); Wen-Tsai Yen, Caotun Township (TW); Yung-Sheng Chiu, Hsinchu City (TW)

(72) Inventors: Wen-Chin Lee, Baoshan Township (TW); Liang-Sheng Yu, Kaohsiung City (TW); Wen-Tsai Yen, Caotun Township (TW); Yung-Sheng Chiu, Hsinchu City (TW)

(73) Assignee: Taiwan Semiconductor Manufacturing Co., Ltd., Hsin-Chu (TW)

(21) Appl. No.: 13/295,148

(22) Filed: Nov. 14, 2011

(51) Int. Cl. H01L 31/0224; H01L 31/18

(52) U.S. Cl. 136/256; 438/57; 257/E31.124

(57) ABSTRACT

A thin film solar cell and process for forming the same. The solar cell includes a bottom electrode layer, a light absorbing semiconductor layer, and top electrode layer. The absorber layer includes a p-type interior region and an n-type exterior region formed around the perimeter of the layer from a modified native portion of the p-type interior region, thereby forming an active n-p junction that is an intrinsic part of the absorber layer. The top electrode layer is electrically connected to the bottom electrode layer via a scribe line formed in the absorber layer that defines sidewalls. The n-type exterior region of the absorber layer extends along both the horizontal top of the absorber layer, and onto the vertical sidewalls of the scribe line to increase the area of available n-p junction in the solar cell thereby improving solar conversion efficiency.

### FIELD OF THE INVENTION

The present invention generally relates to photovoltaic solar cells, and more particularly to thin film solar cells.

### BACKGROUND

Thin film photovoltaic (PV) solar cells are one class of energy source devices which harness a renewable source of energy in the form of light that is converted into useful electrical energy which may be used for numerous applications. Thin film solar cells are multi-layered semiconductor structures formed by depositing various thin layers and films of semiconductor and other materials on a substrate. These solar cells may be made into light-weight flexible sheets in some forms comprised of a plurality of individual electrically interconnected cells. FIG. 1A shows such a conventional solar cell sheet formed of a plurality of individual thin film solar cells which are electrically interconnected. The attributes of light weight and flexibility gives thin film solar cells broad potential applicability as an electric power source for use in portable electronics, aerospace, and residential and commercial buildings where they can be incorporated into various architectural features such as roof shingles, facades, and skylights.

Thin film solar cells utilize an active light absorbing layer which converts light into electrical energy. Absorbing layers have been made from various materials including amorphous silicon, cadmium telluride (CdTe), and copper indium gallium diselenide (CIGS). The latter two foregoing materials are included in the group of semiconductors compounds referred to as chalcogenides, which are binary compounds that also includes cadmium sulfide (CdS). Chalcogenides include elements from Group VIA of the Periodic Table which includes Sulfur (S), Selenium (Se), telluride (Te), and polonium (Po). Chalcogenides are known for being good photoconductors with high absorption coefficients. CIGS-based thin film solar cells are particularly promising and solar conversion efficiencies as high as 19.9 percent have been reported (National Renewable Energy Laboratory).

FIG. 1B is an enlarged cross-sectional detail of a portion of the conventional thin film solar cell shown in FIG. 1A. As shown, a conventional semiconductor solar cell basically includes a substrate which may be glass, a layer of molybdenum (Mo) thereon which forms a bottom electrode, a doped p-type absorber layer is formed thereon which may be CIGS, an n-type buffer layer which may be CdS is formed thereon to create an electrically active n-p junction, and a doped n-type top electrode is formed thereon which may be a TCO (Transparent Conductive Oxide) material such as ZnO. The CdS buffer layer creates an active n-p junction for generating electricity from light energy.

As further shown in FIG. 1C, the individual thin film solar cells each have an associated electric power generation output and are typically interconnected into an array of series or parallel connected solar cells to form a PV module that produces a given amount of current and/or voltage. The individual solar cells are connected to bus lines typically disposes at opposing ends of the module as shown for connection to an external circuit. Individual modules may in turn may be connected to other modules and/or to junction boxes to combine and increase the power output from an array of PV modules.

As shown in FIG. 1B, micro-channels are patterned and scribed into the semiconductor structure to interconnect the various conductive material layers and to separate adjacent solar cells. These micro-channels or “scribe lines” as commonly referred to in the art are given “P” designations related to their function and step during the semiconductor solar cell fabrication process. The P1 and P3 scribe lines are essentially for cell isolation. P2 scribe lines form a connection. P2 scribe lines remove absorber material to interconnect the top TCO electrode to the bottom Mo electrode thereby preventing the intermediate buffer layer from acting as a barrier between the top and bottom electrodes. P3 scribe lines extend completely through the TCO, buffer layer, and absorber layer to the bottom Mo electrode to isolate each cell defined by the P1 and P2 scribe lines.

In the conventional process, only the top of the CIGS absorber layer covered by the CdS buffer forms a high quality active n-p junction for collecting electrical current generated by the absorber layer. Although the material from the top TCO electrode layer extends down through the P2 scribe line as shown in FIG. 1B, the vertical walls of the P2 scribe lines do not provide a good interface and high quality active n-p junction rendering the sidewalls essentially inactive for current collection. This limits the current density, power output potential, and efficiency of such thin film solar cells with only a top CdS buffer layer above the absorber layer.

An improved thin film solar cell is desired with increased potential for greater electric power generation and solar conversion efficiencies.

### SUMMARY

A thin film solar cell is provided that advantageously yields higher energy output and increased solar conversion efficiency than prior thin film cells. This is achieved in the present invention by taking advantage of and forming an active high quality n-p junction area on the available sidewalls of P2 scribe lines, which heretofore have not been utilized for current collection. This increases the efficiency of the solar cell by providing a greater surface area of active n-p regions on the solar cell for improved current collection and density, without increasing the size of the cell. The increase in efficiency is attributable to less trapping and recombination of charge carriers at the interface between the absorber layer and TCO top electrode layer. The use of a separate buffer layer such as CdS as used in prior processes is eliminated from the present process.

According to another aspect of the invention, a buffer-free method and process is provided for forming the foregoing thin film solar cells disclosed. This process eliminates the step of forming a conventional CdS buffer layer on the p-type absorbing layer. Instead, the present process preferably includes a step for modifying and converting the existing p-type surface regions of the absorber layer into a doped n-type material for current collection, thereby forming a buried n-p junction. The n-type exterior surface region extends not only on the top portion of the absorber layer, but beneficially also down along the vertical sidewall portions within the P2 scribe line. Beneficially, no extra process steps are needed or addition expense incurred since the conversion step may be substituted for the buffer layer formation step. Accordingly, the process flow is not disturbed or drastically altered.

In one embodiment according to the present invention, a thin film solar cell includes a bottom electrode layer formed on a substrate, a semiconductor absorber layer formed on the bottom electrode layer and having a p-type interior region and an n-type exterior region formed from a modified native portion of the p-type region. The n-type and p-type regions form an n-p junction that is an intrinsic part of the absorber layer. A top electrode layer is formed directly on the absorber layer, and more particularly on the n-type exterior regions. The top electrode layer is electrically connected to the bottom electrode layer via a scribe line that defines sidewalls in the absorber layer. Preferably, the n-type exterior region of the absorber layer extends into the sidewalls of the scribe line in the absorber layer, and in preferred embodiments also on the top surface portions of the absorber layer.

The scribe line may be a P2 scribe line forming a vertical channel through the absorber layer to a top surface of the bottom electrode. The scribe line is filled with material from the top electrode layer that contacts the vertical n-type exterior region of the absorber layer. In some embodiments, the absorber layer may be comprised of chalcogenide materials. CIGS is one preferred chacogonide material that may be used.

According to another aspect of the present invention, an exemplary process for forming a buffer free thin film solar cells is provided. A buffer free process for forming a thin film solar cell may include the steps of: forming a conductive bottom electrode layer on a substrate; forming a p-type absorber layer on the bottom electrode layer; forming an open scribe line in the absorber layer, the scribe line defining exposed sidewalls on the absorber layer; and converting the exposed sidewalls of the p-type absorber layer within the scribe line into n-type exterior regions. The process may further include a step of depositing a conductive top electrode material on the absorber layer including in the scribe line; the n-type exterior region of the sidewalls being disposed between the top electrode material within the scribe line and the p-type interior regions of the absorber layer.

In one embodiment, a partial electrolyte chemical bath deposition (CBD) process is used to convert the sidewall region of the p-type absorber layer within the scribe line into the n-type exterior region. Preferably, the CBD process is sulfur free in some embodiments which modifies and converts only the surface regions of the absorber layer into n-type material, while the interior regions remain p-type to form an n-p junction there between.

According to another embodiment of a buffer free process for forming a thin film solar cell, the process may include the steps of: forming a conductive bottom electrode layer on a substrate; forming a p-type absorber layer on the bottom electrode layer, the absorber layer having an exposed horizontal top surface; forming an open P2 scribe line in the absorber layer, the scribe line forming exposed vertical sidewalls on the absorber layer and exposing a top surface of the bottom electrode layer; immediately after forming the scribe line, converting the exposed sidewalls and top surface of the p-type absorber layer within the scribe line into n-type regions, wherein the absorber layer has an interior region that remains p-type; and forming a conductive top electrode layer above the absorber layer. The step of forming the top electrode layer preferably includes filling the scribe line with material from the top electrode layer to interconnect the top electrode layer with the bottom electrode layer. The n-type exterior region of the sidewalls is disposed between the top electrode material within the scribe line and the p-type interior regions of the absorber layer. A further step of forming a P3 scribe line through the top electrode layer may be performed to separate the top electrode layer into individual cells.

The thin film solar cell fabrication processes described herein may be performed using any suitable commercially available equipment commonly used in the art to manufacture thin film solar cells.

### BRIEF DESCRIPTION OF THE DRAWINGS

The features of the preferred embodiments will be described with reference to the following drawings where like elements are labeled similarly, and in which:

FIG. 1A is a perspective view of a conventional thin film solar cell;

FIG. 1B is an enlarged cross-sectional detail thereof;

FIG. 1C is a side elevation view thereof;

FIG. 2 shows sequential steps in a conventional prior art thin film solar cell fabrication process including formation of a buffer layer; and

FIGS. 3-9 show sequential steps in an exemplary buffer-free semiconductor device fabrication process according to an embodiment of the present invention;

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. The term “adjacent” as used herein to describe the relationship between structures/components includes both direct contact between the respective structures/components referenced and the presence of other intervening structures/components between respective structures/components. Moreover, the features and benefits of the invention are illustrated by reference to the preferred embodiments. Accordingly, the invention expressly should not be limited to such preferred embodiments illustrating some possible non-limiting combination of features that may exist alone or in other combinations of features; the scope of the invention being defined by the claims appended hereto.

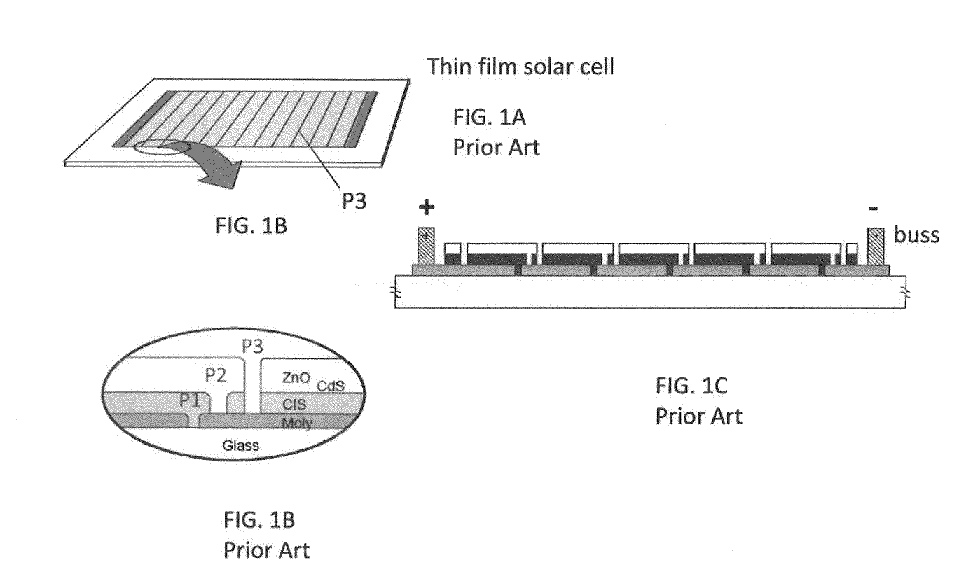

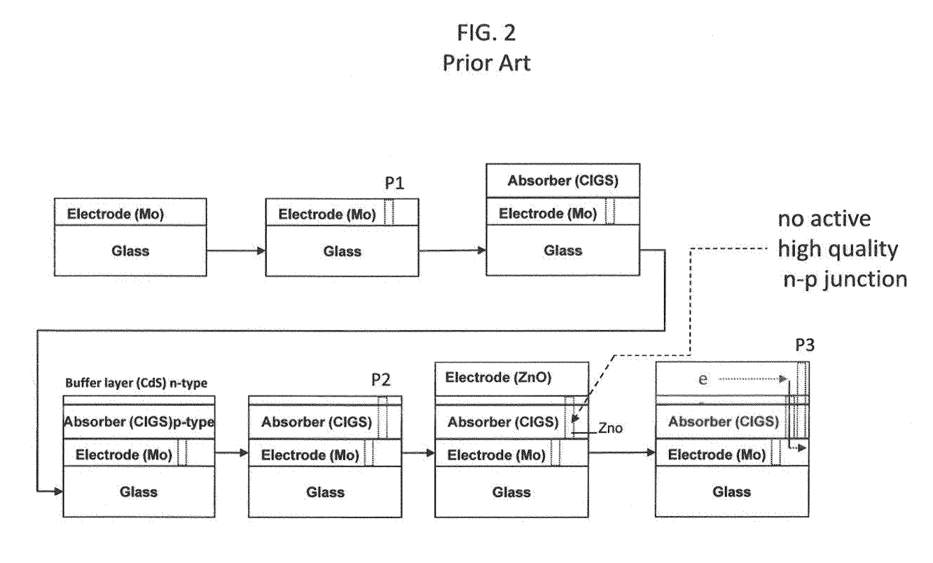

FIG. 2 sequentially shows the basic steps in a conventional process for forming CIGS-based thin film solar cells such as that shown in FIG. 1B, which utilize an n-type CdS buffer layer to provide an electrically active n-p junction between the p-type absorber layer and n-type TCO (transparent conductive oxide) layer. This process is well known those skilled in the art without need for further explanation. Notably, in sequence, the n-type CdS buffer layer is deposited on the CIGS absorber layer, the P2 scribe line is then patterned and formed down to the bottom Mo electrode, and the TCO top electrode layer is deposited which also fills the P2 scribe line as shown. As previously described herein, the vertical walls of the P2 scribe line do not form an active n-p junction for electrical current collection. Only the horizontal interface surfaces between the CIGS absorber layer and ZnO top via the CdS buffer layer is an electrically active region.

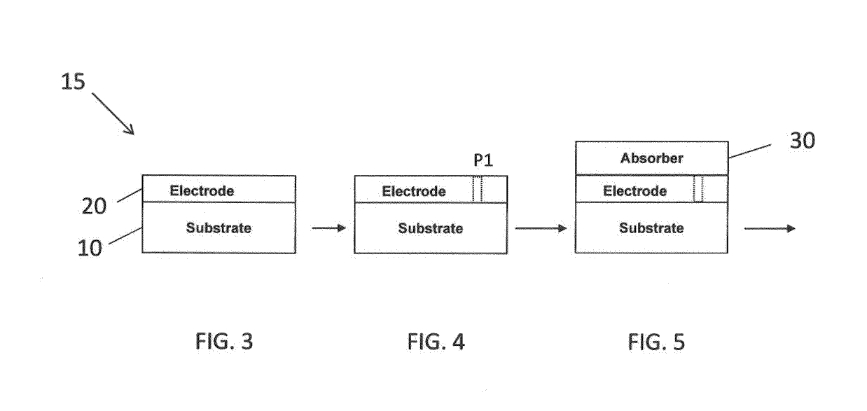

FIGS. 3-8 sequentially show an exemplary but non-limiting method or process for forming thin film solar cells 15 according to the present invention. Preferably, this is a buffer free process wherein the need for forming a separate CdS buffer layer to create an electrically active n-p junction between the absorber layer and TCO top electrode is eliminated. As further described herein, present process preferably performs a surface conversion of the CIGS absorber layer itself to an n-type material for forming a buried electrically active n-p junction. The n-type surface conversion extends not only on the top of the absorber layer, but also down along the side walls of the P2 scribe line to expand the active n-p regions of the solar cell for collecting current.

Referring now to FIG. 3, a bottom electrode layer 20 is first formed on a substrate 10 by any conventional method commonly used in the art including without limitation sputtering. In one embodiment, a preferred material for bottom electrode layer 20 material may be molybdenum (Mo); however, other suitable electrically conductive metallic and semiconductor materials conventionally used in the art may be used such as Al, Ag, Sn, Ti, Ni, stainless steel, ZnTe, etc. Suitable conventional materials that may be used for substrate 10 include without limitation glass such as for example without limitation soda lime glass, ceramic, metals such as for example without limitation thin sheets of stainless steel and aluminum, or polymers such as for example without limitation polyamides, polyethylene terephthalates, polyethylene naphthalates, polymeric hydrocarbons, cellulosic polymers, polycarbonates, polyethers, and others. In one preferred embodiment, glass may be used for substrate 10.

In some representative embodiments, without limitation, bottom electrode layer 20 may preferably have a thickness ranging from about and including 0.1 to 1.3 microns (μm). In one embodiment, layer 20 has a representative thickness on the order of about 0.5 μm.

Referring to FIG. 4, P1 patterned scribe lines are next formed in bottom electrode layer 20 to expose substrate 10 as shown. Any suitable scribing method commonly used in the art may be used such as without limitation mechanical scribing with a stylus or laser scribing. In one embodiment, laser scribing is used for P1 patterning.

Referring to FIG. 5, a p-type doped semiconductor light absorber layer 30 is next formed on bottom electrode layer 20. In preferred embodiment, absorber layer 30 preferably may be a chalcogenide material, and more preferably CIGS Cu(In,Ga)Se₂ in a preferred embodiment. Other suitable chalcogenide materials may be used including without limitation Cu(In,Ga)(Se, S)₂ or “CIGSS,” CuInSe₂, CuGaSe₂, CuInS₂, and Cu(In,Ga)S₂.

Suitable p-type dopants that may commonly be used for forming absorber layer 30 include Cu vacancy (V_{Cu}), In vacancy (V_{In}), or Cu_{In}.

Absorber layer 30 formed of CIGS may be formed by any suitable vacuum or non-vacuum process conventionally used in the art. Such processes include, without limitation, selenization, sulfurization, evaporation, sputtering electrodeposition, chemical vapor deposition, etc. CIGS co-evaporation with max. substrate temperature 450˜700° C. or two step process (precursor sputter and selenization/sulfurization with max. process temperature 400˜700° C.) are preferred in one embodiment.

In some representative embodiments, without limitation, absorber layer 30 may preferably have a thickness ranging from about and including 0.3 to 3 microns (μm). In one embodiment, absorber layer 30 has a representative thickness on the order of about 1.5 μm.

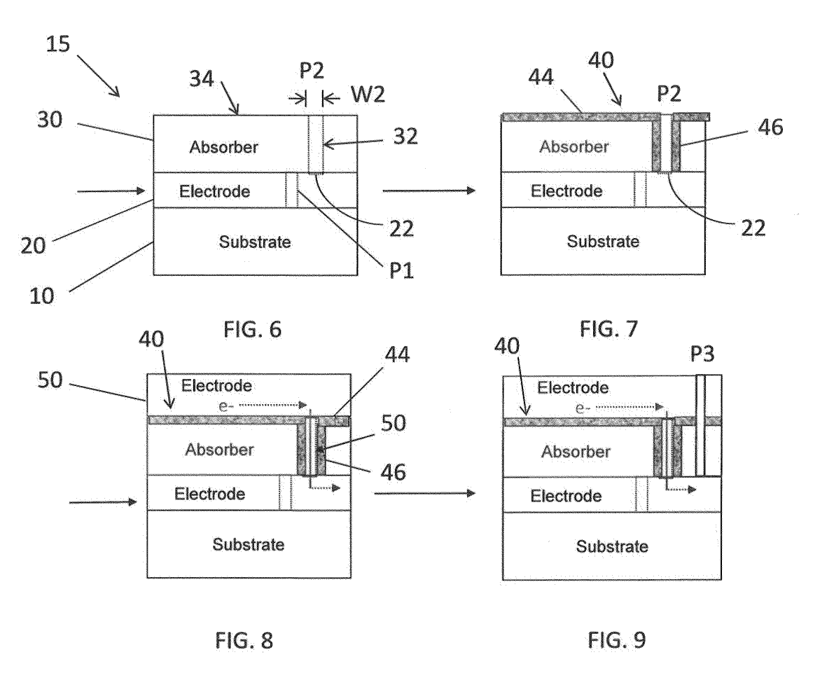

Referring to FIG. 6, after forming absorber layer 30, the P2 scribe line is next cut through the absorber layer to expose the top surface 22 of the bottom electrode 20 within the open scribe line or channel. Any suitable method conventionally used in the art may be used to cut the P2 scribe line as previously described, including without limitation mechanical (e.g. cutting stylus) or laser scribing. In some representative embodiments, without limitation, the P2 scribe line may have a typical width W2 measured in the longitudinal direction of solar cell 15 of about 20˜100 μm. The P2 scribe line will later be filled with a conductive material to interconnect a top electrode layer 50 to the bottom electrode layer 20. The P2 scribe line cutting defines vertical sidewalls 32 in absorber layer 30 within the scribe line, and as shown in FIGS. 1A and 1B, sidewalls 32 extend in a lateral direction across the solar cell perpendicular to the longitudinal length of the cell.

Referring to FIG. 7, a surface region conversion step is next performed to convert exposed horizontal and vertical native exterior surface portions of the existing p-type absorber layer 30 into an integral n-type exterior region 40 formed from modifying the p-type absorber layer material itself. Notably, this step modifies and converts the exposed exterior regions of the p-type absorber layer 30 base material into n-type regions that are an intrinsic part of the absorber layer, but does not produce a separate and discrete n-type film or layer like the CdS buffer layer used in the prior known processes. Advantageously, in conjunction with the interior regions 42 of p-type absorber layer 30 that remain p-type after this conversion process, the n-type exterior region 40 formed in this step creates a high quality n-p junction.

The modified n-type exterior region 40 actively and effectively generates and collects electrical current. Advantageously, this non-CdS n-type exterior region 40 has a high bandgap window than prior used CdS buffer films which improves the current output of the solar cell.

This exterior surface region conversion preferably occurs in both the exposed top surface 34 of the absorber layer 30, and importantly along the exposed sidewalls 32 within the P2 scribe lines which were previously opened by the step shown in FIG. 6 for this specific purpose before forming an n-p junction. By contrast, in the prior conventional thin film solar cell fabrication process described herein in FIG. 2, the P2 scribing is performed after the deposition of the separate CdS buffer layer to interconnect the top and bottom electrodes. It will further be readily apparent that the need for a separate n-type buffer layer such as a CdS layer on the absorber layer 30 as in the prior art process is therefore eliminated.

In cross-section, as shown in FIG. 7, the n-type exterior regions 40 form an n-type perimeter region around the p-type interior region 42 portions of the absorber layer 30 base material. A hybrid unitary structure combining both n-type and p-type materials is thus formed.

Advantageously, this new thin film solar cell structure with n-type exterior region 40 is superior to the prior art solar cell described herein because the added n-type vertical sidewall surface portions 46 within the P2 scribe lines of absorber layer 30 are modified and converted into active high quality active n-p junctions in addition to the top surface portions 44 of absorber layer 30. Therefore, the total surface area in solar cell 15 having active n-p junction regions is greatly expanded in contrast to the prior conventional solar cell structure because, as shown in FIG. 1A, the P2 scribe lines each extend laterally across the width of the solar cell. In a preferred embodiment, therefore, the n-type exterior region 40 therefore includes both horizontal top surface portions 44 and vertical sidewall surface portions 46 extending along the sidewalls 32 of the P2 scribe line (see FIG. 7). Collectively, this is a significant increase in active n-p junction area yielding higher cell current output and solar conversion efficiency.

As shown in FIG. 7, in one preferred embodiment, the horizontal top surface portions 44 and vertical sidewall portions 46 of n-type exterior region 40 may be contiguous and form a continuous outer perimeter region of n-type material.

The n-type exterior regions 40 of absorber layer 30 may be formed by any suitable process commonly used in the art to form thin film semiconductor solar cells. In one preferred embodiment, n-type exterior region 40 may be formed by using a partial electrolyte (PE) chemical bath deposition (CBD) process. In some embodiments, the partial electrolyte CBD process may be a CdPE or ZnPE process. Unlike typical CBD processes which are well known and commonly used for forming a barrier layers in solar cells, the partial electrolyte solution used for form n-type exterior region 40 preferably omits sulfur. This sulfur-free bath operates to convert only the exposed exterior surface regions of p-type absorber layer 30 (to a limited depth) into an n-type doped material. The remaining interior regions 42 of absorber layer 30 more distal to the exposed surfaces remain p-type, thereby forming an n-p junction which is generally free of the interface defects that result when using separate and different materials such as the n-type CdS barrier layer and the CIGS absorber layer used in the conventional solar cell construction to form the n-p junction. Beneficially, the partial electrolyte CBD process produces less waste than conventional CdS CBD processes used to form a buffer layer.

In one preferred embodiment, the partial electrolyte solution used may be cadmium, zinc, or Indium based, or elements can form +2 or +3 ion in the present CBD process. The solution may therefore include cadmium or zinc and ammonia.

In one representative and non-limiting embodiment, for example, in the CBD bath, NH4OH concentration may be 0.05˜3M, Cd²⁺ may be 0.1˜150 mM, bath temperature may be 50˜90C and process time may be a few minutes to 60 minutes. Other suitable bath compositions and process parameters may be used in other embodiments.

The n-type modified exterior region 40 of p-type absorber layer 30 extends inwards adjacent to the top surface 34 and sidewalls 32 in the P2 scribe line for a certain depth or thickness as shown in FIG. 7. In some representative embodiments, without limitation, the depth or thickness of n-type exterior region 40 in absorber layer 30 may preferably range from about and including 20 nm to about and including 100 nm. These thicknesses have worked successfully in producing a conversion layer 40 that displays good n-p junction characteristics. Preferably, conversion layer 40 has a depth or thickness that is less than about 200 nm as greater thicknesses are difficult to produce from a practical standpoint by some present processes.

In other embodiments, other conventional semiconductor solar cell fabrication process may be used to form n-type exterior region 40, including without limitation MO-CVD, ALD, ion implantation, or others, followed by thermal treatment or not. Preferably, the PE-CBD conversion process or other process used for forming n-type exterior region 40 in absorber layer 30 should be capable of converting the exposed surface regions of the p-type absorber layer into n-type material while leaving the p-type interior region 42 of the absorber layer intact for forming an n-p junction.

Importantly, the process selected for forming n-type exterior regions 40 in CIGS absorber layer 30 should preferably have the characteristic of forming a modified material layer on the vertical sidewalls 32 of the P2 scribe line in the absorber layer without filling the scribe line. Otherwise, it would be not be possible to connect the top electrode layer 50 (to be subsequently formed in the process) to the bottom electrode layer 20 if material from n-type exterior region 40 were to completely fill the P2 scribe line.

Referring to FIG. 8, after forming n-type exterior region 40 in absorber layer 30, a light transmitting n-type doped top electrode layer 50 preferably made of a TCO material is next formed on absorber layer 30 for collecting current (electrons) from the cell and preferably absorbing a minimal amount of light which passes through to the light absorbing layer 30. Aluminum is one possible n-type dopant that is commonly used for TCO top electrodes in thin film solar cells; however, others suitable conventional dopants may be used. In one embodiment, electrode layer is formed directly onto n-type exterior region 40 which is an integral and unitary n-type doped portion of absorber layer 30 in

The P2 scribe line is preferably filled with the TCO material a shown in FIG. 8 to form an electrical connection between the top electrode layer 50 and bottom electrode 20 creating an electron flow path as shown. Also significantly, the TCO material contacts the vertical portions 46 of the n-type exterior region 40 on absorber layer 30 which covers the sidewalls 32 of the P2 scribe line (see FIGS. 6-8). Advantageously, this creates additional active surface area for the collection of current by the top electrode which carries the charge to an external circuit.

In one embodiment, the TCO used for top electrode layer 50 may be any conventional material commonly used in the art for thin film solar cells. Suitable TCOs that may be used include without limitation zinc oxide (ZnO), fluorine tin oxide (“FTO” or SnO₂:F), indium tin oxide (“ITO”), indium zinc oxide (“IZO”), antimony tin oxide (ATO), a carbon nanotube layer, or any other suitable coating materials possessing the desired properties for a top electrode. In one preferred embodiment, the TCO used is ZnO.

In some possible embodiments (not shown), a thin intrinsic ZnO film may be first formed on top of absorber layer 30 followed by forming the thicker n-type doped TCO top electrode layer 50 which has been reported to improve cell performance.

Following formation of the TCO top electrode, the P3 scribe line is formed in thin film solar cell 15 as shown in FIG. 9 similarly to the P3 scribe step shown in the conventional process (see also FIG. 2). The P3 scribe line extends through (from top to bottom) top electrode layer 50, n-type exterior region 40 of absorber layer 30, and the absorber layer to the top of the Mo bottom electrode layer 20.

Suitable front conductive grid contacts and one or more anti-reflective coatings (not shown) may further be formed above top electrode 50 in a conventional manner well known in the art. The grid contacts will protrude upwards through and beyond the top surface of any anti-reflective coatings for connection to external circuits. Additional back end of line processes and lamination may be performed following formation of the thin film solar cell structure disclosed herein, as will be understood by those skilled in the art. This may include laminating a top cover glass onto the cell structure with a suitable encapsulant such as EVA, butyl to seal the cell.

It should be generally noted that suitable n-type and p-type dopants and processes used to dope the materials for fabricating the layers and films described herein for the disclosed thin film solar cell are well known in the art without need for further elaboration.

The advantage of the buffer free process and thin film solar cell formed therewith are increased solar conversion efficient by forming a more active n-p junction between the absorber layer and TCO top electrode with less recombination at the interface, and no additional fabrication process step or cost.

While the foregoing description and drawings represent preferred or exemplary embodiments of the present invention, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. One skilled in the art will further appreciate that the invention may be used with many modifications of structure, arrangement, proportions, sizes, materials, and components and otherwise, used in the practice of the invention, which are particularly adapted to specific environments and operative requirements without departing from the principles of the present invention. In addition, numerous variations in the preferred or exemplary methods and processes described herein may be made without departing from the spirit of the invention. The presently disclosed embodiments are therefore to be considered in all respects as illustrative and not restrictive, the scope of the invention being defined by the appended claims and equivalents thereof, and not limited to the foregoing description or embodiments. Rather, the appended claims should be construed broadly, to include other variants and embodiments of the invention, which may be made by those skilled in the art without departing from the scope and range of equivalents of the invention.

What is claimed is:

1. A thin film solar cell comprising:
a bottom electrode layer formed on a substrate;
a semiconductor absorber layer formed on the bottom electrode layer, the absorber layer having a p-type interior region and an n-type exterior region formed from a modified native portion of the p-type region, wherein the n-type and p-type regions form an n-p junction that is an intrinsic part of the absorber layer; and
a top electrode layer formed on the absorber layer, the top electrode layer being electrically connected to the bottom electrode layer via a scribe line defining sidewalls in the absorber layer;
wherein the n-type exterior region of the absorber layer extends onto the sidewalls within the scribe line.

2. The solar cell of claim 1, wherein the n-type exterior region includes a horizontal top portion of the absorber layer and a vertical portion of the absorber layer extending along the sidewalls of the scribe line.

3. The solar cell of claim 2, wherein the top portion and vertical portions of the n-type exterior regions are contiguous.

4. The solar cell of claim 2, wherein the scribe line is a P2 scribe line forming a vertical channel through the absorber layer to a top surface of the bottom electrode, the scribe line being filled with material from the top electrode layer that contacts the vertical n-type exterior region of the absorber layer.

5. The solar cell of claim 1, wherein the n-type exterior region has a depth equal to or less than 200 nm.

6. The solar cell of claim 5, wherein the n-type exterior region has a depth of about and including 20 nm to about and including 100 nm.

7. The solar cell of claim 1, wherein the absorber layer is comprised of chalcogenide materials.

8. The solar cell of claim 7, wherein the absorber layer is comprised of a material selected from the group consisting of Cu(In,Ga)Se₂, Cu(In,Ga)(Se, S)₂, CuInSe₂, CuGaSe₂, CuInS₂, and Cu(In,Ga)S₂.

9. The solar cell of claim 1, wherein the top electrode is selected from the group consisting of zinc oxide, fluorine tin oxide, indium tin oxide, indium zinc oxide, antimony tin oxide (ATO), and a carbon nanotube layer.

10. The solar cell of claim 1, wherein the bottom electrode layer is molybdenum.

11. The solar cell of claim 1, wherein the substrate is glass.

12. A method for forming a thin film solar cell comprising:
forming a conductive bottom electrode layer on a substrate;
forming a p-type absorber layer on the bottom electrode layer;
forming an open scribe line in the absorber layer, the scribe line defining exposed sidewalls on the absorber layer; and
converting the exposed sidewalls of the p-type absorber layer within the scribe line into n-type exterior regions.

13. The method of claim 12, wherein the n-type exterior regions are a modified intrinsic portion of the absorber layer.

14. The method of claim 12, wherein a partial electrolyte chemical bath deposition (CBD) process is used to convert the sidewall region of the p-type absorber layer within the scribe line into the n-type exterior region.

15. The method of claim 12, wherein interior regions of the absorber layer below the n-type exterior regions remain p-type material after the converting step.

16. The method of claim 15, further comprising a step of depositing a conductive top electrode material on the absorber layer including in the scribe line, the n-type exterior region of the sidewalls being disposed between the top electrode material within the scribe line and the p-type interior regions of the absorber layer.

17. The method of claim 12, wherein the scribe line exposes a top surface of the bottom electrode layer beneath the absorber layer for connecting the bottom electrode layer to a top electrode layer formed above the absorber layer.

18. A method for forming a thin film solar cell comprising:
forming a conductive bottom electrode layer on a substrate;
forming a p-type absorber layer on the bottom electrode layer, the absorber layer having an exposed horizontal top surface;
forming an open scribe line in the absorber layer, the scribe line forming exposed vertical sidewalls on the absorber layer and exposing a top surface of the bottom electrode layer;
converting the exposed sidewalls and top surface of the p-type absorber layer within the scribe line into n-type regions immediately after forming the scribe line, wherein the absorber layer has an interior region that remains p-type; and
forming a conductive top electrode layer above the absorber layer.

19. The method of claim 18, wherein forming the top electrode layer includes filling the scribe line with material from the top electrode layer to interconnect the top electrode layer with the bottom electrode layer.

20. The method of claim 18, wherein the converting step is performed using a sulfur-free partial electrolyte chemical bath deposition (CBD) process that modifies a portion of the p-type absorber layer into the n-type regions adjacent the top surface and sidewalls of the absorber layer.
